(19) United States
(12) Patent Application Publication
(10) Pub. No.: US 2022/0274223 A1
(43) Pub. Date: Sep. 1, 2022

(54) APPARATUS FOR GRINDING SURFACE OF SUBSTRATE

(71) Applicant: HAESUNG DS CO., LTD., Gyeongsangnam-do (KR)

(72) Inventors: Jong Hoe Ku, Gyeongsangnam-do (KR); Sung Il Kang, Gyeongsangnam-do (KR); I Gyun Kim, Gyeongsangnam-do (KR); Hong Chan Kim, Gyeongsangnam-do (KR); In Seob Bae, Gyeongsangnam-do (KR); Jung Ho Heo, Gyeongsangnam-do (KR)

(21) Appl. No.: 17/652,563

(22) Filed: Feb. 25, 2022

(30) Foreign Application Priority Data
Feb. 26, 2021 (KR) 10-2021-0026702

(51) Int. Cl. B24B 7/12

(52) U.S. Cl. CPC B24B 7/12

(57) ABSTRACT

A substrate surface grinding apparatus includes: a grinding device including a plurality of grinding rollers configured to grind a surface of a substrate; and a substrate support member configured to support the substrate, wherein rotational axes of the grinding rollers are disposed to be inclined to rotational axes of adjacent grinding rollers.

### CROSS-REFERENCE TO RELATED APPLICATION

This application is based on and claims priority under 35 U.S.C. § 119 to Korean Patent Application No. 10-2021-0026702, filed on Feb. 26, 2021, in the Korean Intellectual Property Office, the disclosure of which is incorporated by reference herein in its entirety.

### BACKGROUND

### 1. Field

One or more example embodiments relate to an apparatus for grinding the surface of a substrate.

### 2. Description of the Related Art

With the development of the electronic industry, demands for miniaturization and multifunctionality of electronic components are gradually increasing, and substrates on which electronic components are mounted are formed in various structures and shapes.

The substrate is manufactured to have various structures such as circuit patterns and insulating layers. In order to manufacture the substrate, a process of removing unnecessary layers or materials by grinding the surface of the substrate is sometimes required.

Korean Patent Laid-Open Publication No. 2011-0053753 discloses an apparatus for grinding a substrate having a chemical grinding portion filled with an etchant and a mechanical grinding portion including a brush.

### SUMMARY

One or more embodiments include an apparatus for grinding the surface of a substrate.

Additional aspects will be set forth in part in the description which follows and, in part, will be apparent from the description, or may be learned by practice of the presented embodiments of the disclosure.

According to one or more embodiments, a substrate surface grinding apparatus includes: a grinding device including a plurality of grinding rollers configured to grind a surface of a substrate; and a substrate support member configured to support the substrate, wherein rotational axes of the grinding rollers are disposed to be inclined to rotational axes of adjacent grinding rollers.

A resin layer may be formed on the surface of the substrate, and the grinding device may remove at least a portion of the resin layer.

The substrate support member may be a transfer belt in contact with the substrate.

The substrate surface grinding apparatus may further include a plurality of support rollers respectively disposed to face the grinding rollers with the substrate therebetween.

Arrangement of rotational axes of the support rollers may correspond to arrangement of rotational axes of the grinding rollers respectively facing the rotational axes of the support rollers.

The rotational axes of the adjacent grinding rollers may be symmetrically disposed with respect to a virtual line perpendicular to a transfer direction of the substrate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view illustrating a state in which a grinding roller of a substrate surface grinding apparatus according to an embodiment is disposed;

FIG. 2 is a schematic cross-sectional view illustrating a state of the substrate surface grinding apparatus of FIG. 1 taken along line A-A′;

FIG. 3 is a schematic cross-sectional view illustrating a state of the substrate of FIG. 1 at point I;

FIG. 4 is a schematic cross-sectional view illustrating a state of the substrate of FIG. 1 at point II;

FIG. 5 is a view schematically illustrating a direction of a force applied to a substrate by first and second grinding rollers according to an embodiment; and

FIG. 6 is a view schematically illustrating a shape in which first and second grinding rollers according to an embodiment grind a resin layer.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

Hereinafter, embodiments will be described in detail with reference to the accompanying drawings. The same reference numerals are used to denote the same elements, and repeated descriptions thereof will not be given herein. In addition, parts drawn exaggeratedly for explanation may be present in the accompanying drawings.

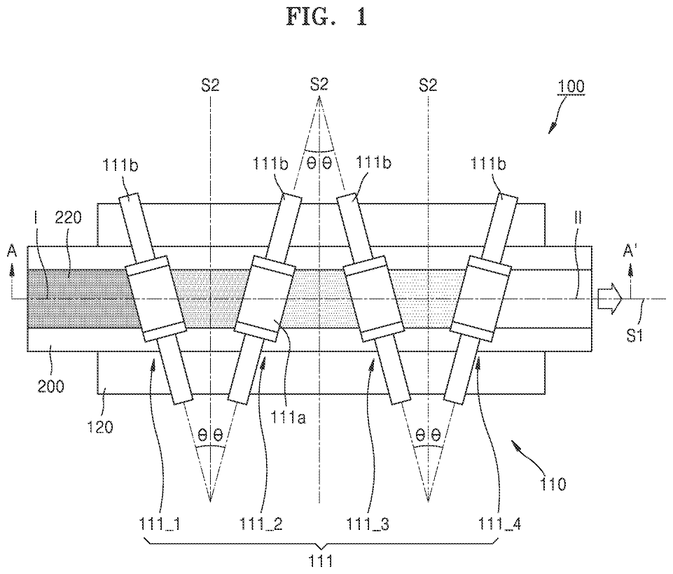

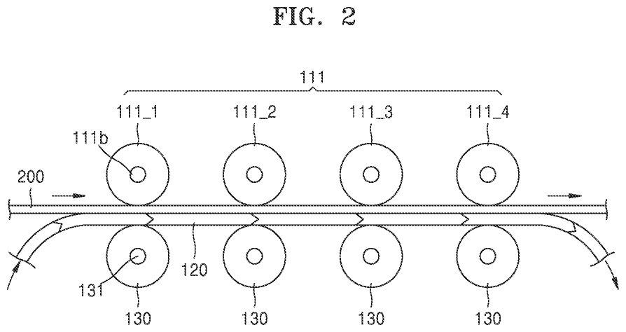

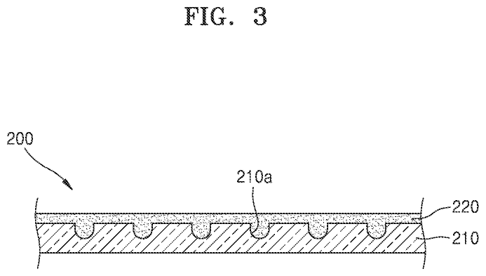

FIG. 1 is a schematic plan view illustrating a state in which a grinding roller of a substrate surface grinding apparatus according to an embodiment is disposed, and FIG. 2 is a schematic cross-sectional view illustrating a state of the substrate surface grinding apparatus of FIG. 1 taken along line A-A′. FIG. 3 is a schematic cross-sectional view illustrating a state of the substrate of FIG. 1 at point I, and IG. 4 is a schematic cross-sectional view illustrating a state of the substrate of FIG. 1 at point II.

As illustrated in FIGS. 1 and 2, a substrate surface grinding apparatus 100 according to an embodiment is an apparatus for grinding the surface of a substrate 200 while transferring the substrate 200 by a roll-to-roll process, and is one of apparatuses for performing a process of manufacturing a substrate for a lead frame.

The substrate surface grinding apparatus 100 according to the present embodiment is an apparatus for grinding a surface of the substrate 200 while transferring the substrate 200 by a roll-to-roll process, but the disclosure is not limited thereto. That is, a substrate surface grinding apparatus according to the disclosure may grind a surface of a substrate while transferring the substrate using a conveyor transfer method or the like when the substrate has a panel shape.

The substrate surface grinding apparatus 100 according to the present embodiment receives the substrate 200 on which a resin layer 220 is formed and grinds the surface.

The shape of the substrate 200 on which the resin layer 220 is formed is shown in FIG. 3. The substrate 200 includes a raw material 210 and the resin layer 220 formed on an upper surface of the raw material 210.

The substrate 200 has the shape of a thin plate, a groove 210a is formed on a surface thereof, and a resin 220a is filled in the groove 210a.

The raw material 210 of the substrate 200 is made of copper, but the disclosure is not limited thereto. That is, as the raw material 210 of the substrate 200, various types of materials used for a lead frame may be used in addition to copper.

The resin layer 220 is formed on the surface of the substrate 200, and as a resin material constituting the resin layer 220, various materials such as a polyimide resin and a general photo-sensitive resist (PSR) resin may be used.

Moreover, the substrate surface grinding apparatus 100 includes a grinding device 110, a substrate support member 120, and a support roller 130.

The grinding device 110 includes a plurality of grinding rollers 111 for grinding the surface of the substrate 200. There are a plurality of grinding rollers 111, but in the present embodiment, the number of grinding rollers 111 is four. That is, the grinding roller 111 includes the first, second, third, and fourth grinding rollers 111_1, 111_2, 111_3, and 111_4.

The grinding device 110 grinds an upper surface of the substrate 200, where the upper surface of the substrate 200 refers to a portion of the substrate 200 to which the grinding roller 111 of the grinding device 110 may contact. In other words, the upper surface of the substrate 200 becomes a surface of the resin layer 220 at the beginning of the grinding process, and becomes an exposed surface of the raw material 210 at the end of the grinding process as the resin layer 220 is gradually grinded and removed.

Each of the first, second, third, and fourth grinding rollers 111_1, 111_2, 111_3, and 111_4 has a grinding layer 111a formed in a cylindrical shape. Because fine grinding particles are attached to the grinding layer 111a, a grinding action occurs when in contact with the surface of the substrate 200. As examples of the grinding particles, various particles such as diamond particles, ceramic particles, and synthetic resin particles may be applied.

According to the present embodiment, although compositions and roughnesses of the grinding layer 111a respectively applied to the first, second, third, and fourth grinding rollers 111_1, 111_2, 111_3, and 111_4 are the same, the disclosure is not limited thereto. That is, according to the disclosure, compositions and roughnesses of the grinding layer 111a respectively applied to the first, second, third, and fourth grinding rollers 111_1, 111_2, 111_3, and 111_4 may be different from each other.

Each of the first, second, third, and fourth grinding rollers 111_1, 111_2, 111_3, and 111_4 is connected to a rotational axis 111b, wherein the rotational axis 111b rotates by receiving power from a driving unit (not shown) or receiving external power, thereby rotating the grinding roller 111.

According to the present embodiment, the grinding device 110 is provided with four grinding rollers 111, but the disclosure is not limited thereto. That is, the number of grinding rollers included in the grinding device according to the disclosure may be plural, and there is no particular limitation on the number. For example, the number of grinding rollers provided in the grinding device may be 2, 3, 5, 6, or the like.

The rotational axis 111b of each of the first, second, third, and fourth grinding rollers 111_1, 111_2, 111_3, and 111_4 is disposed to be inclined to each other with the rotational axes 111b of the adjacent grinding rollers 111. As illustrated in FIG. 1, the rotational axes 111b of the adjacent grinding rollers 111 are symmetrically disposed with respect to a virtual line S2 perpendicular to the transfer direction S1 of the substrate 200. That is, as shown in FIG. 1, the rotational axes 111b of the grinding rollers 111 are symmetrically inclined by the same angle θ with respect to the virtual line S2.

According to the present embodiment, the rotational axes 111b of the grinding rollers 111 are symmetrically inclined by the same angle θ with respect to the virtual line S2, but the disclosure is not limited thereto. In other words, angles formed by the rotational axes 111b of some of the grinding rollers 111 with the virtual line S2 are not completely the same and may be slightly different from each other.

The substrate support member 120 supports the substrate 200. That is, a lower surface of the substrate 200 is in contact with an upper surface of the substrate support member 120.

The substrate support member 120 is flexible and may have a configuration of a transfer belt in contact with the substrate 200.

As a material of the substrate support member 120, various materials such as natural rubber, synthetic rubber, synthetic resin, and thin metal plate may be used. The substrate support member 120 receives power to move while supporting the substrate 200.

A plurality of support rollers 130 are disposed to respectively face the grinding rollers 111 with the substrate 200 therebetween.

Arrangement of rotational axes 131 of the support rollers 130 is configured to correspond to arrangement of the rotational axes 111b of the grinding rollers 111 respectively facing the support rollers 130. In other words, the rotational axis 131 of the support roller 130 is also disposed to be inclined to the rotational axis 131 of the adjacent support roller 130. That is, the rotational axes 131 of the adjacent support roller 130 are symmetrically disposed with respect to the virtual line S2 perpendicular to the transfer direction S1 of the substrate 200. That is, the rotational axes 131 of the support rollers 130 are inclined by an identical angle based on the virtual line S2. During grinding, the grinding roller 111 processes while pressing the substrate 200. At that time, because the support roller 130 corresponding to each grinding roller 111 supports the grinding roller 111, the grinding process of the substrate 200 is facilitated, and the occurrence of sagging or wrinkles of the substrate 200 due to the grinding process may be prevented.

Although the substrate surface grinding apparatus 100 according to the present embodiment includes the support roller 130, the disclosure is not limited thereto. That is, the substrate surface grinding apparatus according to the disclosure may not include the support roller 130. In this case, the substrate support member 120 is installed to have sufficient tension or a supporting force, or a separate support member supporting the substrate support member 120 is additionally installed to withstand the load applied by the grinding roller 111.

On the other hand, according to the present embodiment, although vibration is not applied to the grinding roller 111 and/or the substrate 200 when the surface of the substrate 200 is grinded, the disclosure is not limited thereto. That is, according to the disclosure, when the surface of the substrate 200 is grinded, the grinding performance may be improved by applying vibration to the grinding roller 111 and/or the substrate 200.

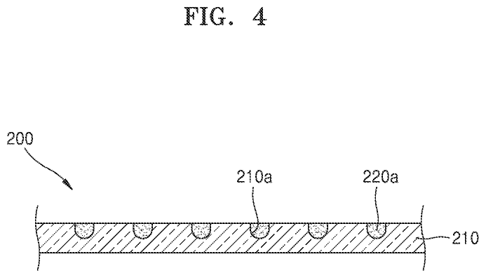

Hereinafter, a grinding operation of a substrate surface using the substrate surface grinding apparatus 100 described above will be described with reference to FIGS. 1 to 6.

First, as shown in FIG. 3, the resin layer 220 is formed on the substrate 200 before grinding.

When the substrate support member 120 and the substrate 200 move and the substrate 200 enters the grinding device 110, the grinding roller 111 rotates while pressing the resin layer 220 formed on the substrate 200. In that case, the grinding layer 111a of the grinding roller 111 grinds the resin layer 220 formed on the surface of the substrate 200, and the resin layer 220 is removed by a certain depth.

In the present embodiment, because the rotational axis 111b of the grinding roller 111 is inclined to the rotational axis 111b of the adjacent grinding roller 111, the resin layer 220 may be stably and evenly grinded, which will be described in detail below.

Unlike the disclosure, it is assumed that the rotational axes 111b of the grinding rollers 111 are arranged parallel to each other. In that case, when an entry direction of the substrate 200 is slightly shifted due to a control error, the grinding device 110 itself does not have a function to correct a moving direction of the substrate 200, and thus, the moving direction of the substrate 200 is also shifted. Then, the grinding action becomes non-uniform and unstable, and the production yield is lowered.

On the contrary, in the present embodiment, because the rotational axes 111b of the adjacent grinding rollers 111 are disposed to be inclined symmetrically with respect to the virtual line S2 perpendicular to the transfer direction S1 of the substrate 200, even if the entry direction of the substrate 200 is slightly shifted, the grinding device 110 itself corrects the moving direction of the substrate 200.

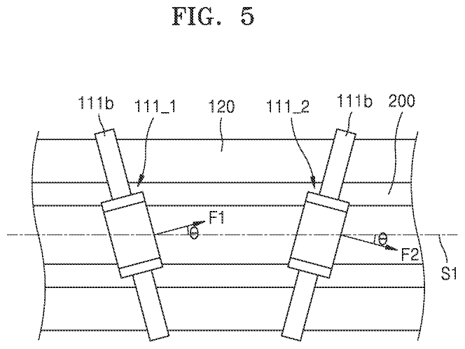

When this is explained with reference to FIG. 5, a force is applied to the surface of the substrate 200 in direction F1 by the rotation of the first grinding roller 111_1, and a force is applied to the surface of the substrate 200 in direction F2 by the rotation of the second grinding roller 111_2. Since direction F1 and direction F2 are directions oriented up and down by θ with respect to the transfer direction S1 of the substrate 200, the moving direction of the substrate 200 may be corrected by itself. Similarly, because the third and fourth grinding rollers 111_3 and 111_4 also apply a force to the surface of the substrate 200, the moving direction of the substrate 200 may be corrected by itself. Accordingly, the grinding action of the resin layer 220 may be stably performed.

In addition, in the present embodiment, in grinding the resin layer 220, grinding patterns by the grinding roller 111 overlap each other in an oblique direction, so that the grinding is performed more effectively and evenly.

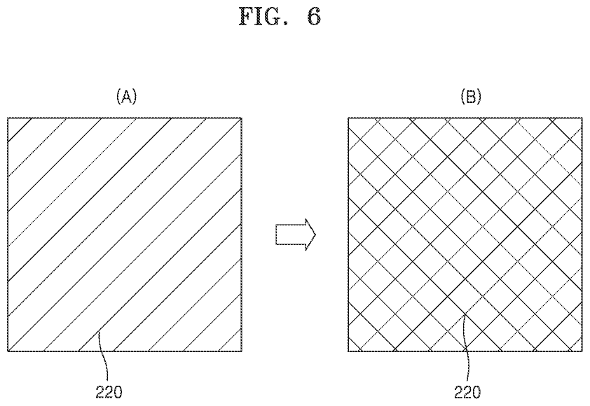

That is, referring to FIG. 6, the resin layer 220 is grinded in an oblique shape as in (A) by the rotation of the first grinding roller 111_1, and then the resin layer 220 moved to the second grinding roller 111_2 is grinded in an oblique shape as in (B) by the rotation of the second grinding roller 111_2, so that an even grinding action becomes possible. Similarly, the third and fourth grinding rollers 111_3 and 111_4 also grind the resin layer 220 in an oblique shape to enable an even grinding action, so that the resin layer 220 may be effectively grinded to a uniform thickness.

As described above, in the substrate surface grinding apparatus 100 according to the present embodiment, because the rotational axis 111b of the grinding roller 111 is disposed to be inclined to the rotational axis 111b of the adjacent grinding roller 111, the grinding action of the resin layer 220 is stably and evenly performed, so that the resin layer 220 may be grinded to a uniform thickness.

According to a substrate surface grinding apparatus according to an aspect of the disclosure, by arranging a rotational axis of a grinding roller to be inclined to a rotational axis of an adjacent grinding roller, a surface of a substrate may be stably grinded.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

### INDUSTRIAL APPLICABILITY

The disclosure may be applied to an apparatus for grinding the surface of a substrate and the like.

What is claimed is:

1. A substrate surface grinding apparatus comprising:
a grinding device including a plurality of grinding rollers configured to grind a surface of a substrate; and
a substrate support member configured to support the substrate,
wherein rotational axes of the grinding rollers are disposed to be inclined to rotational axes of adjacent grinding rollers.

2. The substrate surface grinding apparatus of claim 1, wherein a resin layer is formed on a surface of the substrate, and the grinding device removes at least a portion of the resin layer.

3. The substrate surface grinding apparatus of claim 1, wherein the substrate support member is a transfer belt in contact with the substrate.

4. The substrate surface grinding apparatus of claim 1, further comprising:
a plurality of support rollers respectively disposed to face the grinding rollers with the substrate therebetween.

5. The substrate surface grinding apparatus of claim 4, wherein arrangement of rotational axes of the support rollers corresponds to arrangement of rotational axes of the grinding rollers respectively facing the rotational axes of the support rollers.

6. The substrate surface grinding apparatus of claim 1, wherein the rotational axes of the adjacent grinding rollers are symmetrically disposed with respect to a virtual line perpendicular to a transfer direction of the substrate.
